(19) United States
(12) Patent Application Publication
(10) Pub. No.: US 2025/0092074 A1
(43) Pub. Date: Mar. 20, 2025

(54) METAL CARBONYL COMPLEXES WITH PHOSPHORUS-BASED LIGANDS FOR CVD AND ALD APPLICATIONS

(71) Applicants: Merck Patent GmbH, Darmstadt (DE); Versum Materials US, LLC, Tempe, AZ (US)

(72) Inventors: Paul MEHLMANN, Darmstadt (DE); Lukas MAI, Darmstadt (DE); Lars LIETZAU, Rossdorf (DE); Holger HEIL, Frankfurt am Main (DE); Sergei V. IVANOV, Schnecksville, PA (US)

(21) Appl. No.: 18/729,645

(22) PCT Filed: Mar. 24, 2023
(86) PCT No.: PCT/US2023/016176

§ 371 Date: Jul. 17, 2024

Related U.S. Application Data
(60) Provisional application No. 63/362,012, filed on Mar. 28, 2022.

(51) Int. Cl. C07F 11/00; C23C 16/16; C23C 16/455

(52) U.S. Cl. CPC C07F 11/00; C23C 16/16; C23C 16/45553

(57) ABSTRACT

The disclosed and claimed subject matter relates to metal (e.g., Cr, Mo and W) carbonyl complexes with phosphorus-based ligands having improved (i.e., higher) thermal stability and low melting points, compositions containing the compounds and methods of using the compounds as precursors for deposition of metal-containing films.

### BACKGROUND

### Field

The disclosed and claimed subject matter relates to molybdenum carbonyl complexes with phosphorus-based ligands having improved (i.e., higher) thermal stability and low melting points, compositions containing the compounds and methods of using the compounds as precursors for deposition of metal-containing films.

### Related Art

Transition metal-containing films are used in semiconductor and electronics applications. Chemical Vapor Deposition (CVD) and Atomic Layer Deposition (ALD) have been applied as the main deposition techniques for producing thin films for semiconductor devices. These methods enable the achievement of conformal films (metal, metal oxide, metal nitride, metal silicide, and the like) through chemical reactions of metal-containing compounds (precursors). The chemical reactions occur on surfaces which may include metals, metal oxides, metal nitrides, metal silicides, and other surfaces. In CVD and ALD, the precursor molecule plays a critical role in achieving high quality films with high conformality and low impurities. The temperature of the substrate in CVD and ALD processes is an important consideration in selecting a precursor molecule. Higher substrate temperatures, in the range of 150 to 500 degrees Celsius (° C.), promote a higher film growth rate. The preferred precursor molecules must be stable in this temperature range. The preferred precursor is capable of being delivered to the reaction vessel in a liquid phase. Liquid phase delivery of precursors generally provides a more uniform delivery of the precursor to the reaction vessel than solid phase precursors.

CVD and ALD processes are increasingly used as they have the advantages of enhanced compositional control, high film uniformity, and effective control of doping. Moreover, CVD and ALD processes provide excellent conformal step coverage on highly non-planar geometries associated with modern microelectronic devices. CVD and ALD are specifically attractive for fabricating conformal metal containing films on substrates, such as silicon, silicon oxide, metal nitride, metal oxide and other metal-containing layers, using these metal-containing precursors. In these techniques, a vapor of a volatile metal complex is introduced into a process chamber where it contacts the surface of a silicon wafer whereupon a chemical reaction occurs that deposits a thin film of pure metal or a metal compound.

CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Plasma can be used to assist in reaction of a precursor or for improvement of material properties. Volatile by-products are removed by gas flow through the reaction chamber. The deposited film thickness can be difficult to control because it depends on coordination of many parameters such as temperature, pressure, gas flow volumes and uniformity, chemical depletion effects, and time. Thus, CVD occurs where the precursor reacts at the wafer surface either thermally or with a reagent added simultaneously into the process chamber and the film growth occurs in a steady state deposition. CVD can be applied in a continuous or pulsed mode to achieve the desired film thickness.

ALD is a chemical method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over the substrate surface producing a monolayer on the substrate surface. Any excess unreacted precursor is pumped out of the reaction chamber. A second precursor or co-reactant is then passed over the substrate surface and reacts with the first precursor, forming a second monolayer of film over the first-formed monolayer of film on the substrate surface. Plasma may be used to assist with reaction of a precursor or co-reactant or for improvement in materials quality. This cycle is repeated to create a film of desired thickness. ALD provides the deposition of ultra-thin yet continuous metal containing films with precise control of film thickness, excellent uniformity of film thickness and outstandingly conformal film growth to evenly coat deeply etched and highly convoluted structures such as interconnect vias and trenches. Thus, ALD is typically preferred for deposition of thin films on features with high aspect ratio.

Thin films, and in particular thin metal-containing films, have a variety of important applications, such as in nanotechnology and the fabrication of semiconductor devices. Examples of such applications include capacitor electrodes, gate electrodes, adhesive diffusion barriers and integrated circuits. However, the continual decrease in the size of microelectronic components, such as semi-conductor devices, presents several technical challenges and has increased the need for improved thin film technologies. In particular, microelectronic components may include features on or in a substrate, which require filling, e.g., to form a conductive pathway or to form interconnections. Filling such features, especially in smaller and smaller microelectronic components, can be challenging because the features can become increasingly thin or narrow. Consequently, a complete filling of the feature, e.g., via ALD, would require infinitely long cycle times as the thickness of the feature approaches zero. Moreover, once the thickness of the feature becomes narrower than the size of a molecule of a precursor, the feature cannot be completely filled. As a result, a hollow seam can remain in a middle portion of the feature when ALD is performed. The presence of such hollow seams within a feature is undesirable because they can lead to failure of the device. Accordingly, there exists significant interest in the development of thin film deposition methods, particularly ALD methods that can selectively grow a film on one or more substrates and achieve improved filling of a feature on or in a substrate, including depositing a metal-containing film in a manner which substantially fills a feature without any voids.

As alluded to above, in conventional semiconductor device fabrication, patterning is a “top-down” process based largely on photolithography and etching, which is a main bottleneck for device downscaling. In contrast, area selective deposition (e.g., CVD and ALD) provides an alternative “bottom-up” method for patterning for advanced semiconductor manufacturing where a metal layer (e.g., Ru) is grown on bottom metal surface (e.g., Ru and TiN) proximate to the passivated dielectric substrate, but not on a dielectric (e.g., SiO₂) sidewall. See, e.g., FIG. 1. It is also desirable that these processes be oxygen free and/or have lower resistivity.

In another application it is desired to deposit dielectric film only on another dielectric film but not on metal surface. See, e.g., FIG. 2. One potential application for such process is self-aligned fabrication. Most common strategy to achieve selective growth is based on selective passivation of non-growth surface. Small volatile molecules are highly desired for passivation because they can be supplied via vapor phase. Selective passivation of non-metallic surfaces with high concentration of hydroxyl groups is being widely utilized and includes reaction with various silylating agents, such as RₓSiCl_{y}, RₓSi(NR₂)_{y}, etc. On the other hand, selective passivation of metallic surfaces is much more challenging and selectivity by this approach can be easily lost by desorption of passivating agent and incomplete passivation due to residual impurities on the surface of metal film, etc. Typically, single component reagents are used to passivate non-growth surface. However, single component reagents may not provide complete surface coverage of metal surface due to presence of different sites on the metal surface, such as for example “naked” metal, metal terminated with hydrogen atom, metal terminated with oxygen atom or hydroxyl group, etc.

As noted above, in ALD processes, thin films can be deposited by the reaction of a metalorganic precursor with a co-reactant, separated by inert gas purges. Due to that unique mechanism only ALD is able to coat three dimensional (3D) surfaces with an atomic precision which renders it indispensable for the semiconductor industry.

A benchmark precursor for the deposition of Mo-containing materials is molybdenum hexacarbonyl (i.e., Mo(CO)₆). Notwithstanding its excellent volatility for vapor phase deposition methods, the main issue with Mo(CO)₆ is its physical solid state and the narrow ALD window (temperature area in which the precursor undergoes an ALD-like, surface limited process). While the lowest possible deposition temperature is limited by its poor reactivity, its lack of thermal stability limits the temperature window at higher temperatures. The unfavorable thermal properties of Mo(CO)₆ can be attributed to the binding motif of the neutral CO ligand to the Mo(O) center. First, Mo(CO)₆ is an 18-electron complex with strong σ-bondings and π-backbondings and is therefore stable at room temperature with a low reactivity. Second, CO is a stable molecule itself and thus a good leaving group which results in a low thermal stability at elevated temperatures. Consequently, Mo(CO)₆ exhibits very narrow process conditions rending it unsuitable for many practical applications. Furthermore, deposition temperatures close to the decomposition temperature of Mo(CO)₆ are required that may result in increased amounts of impurities in the films.

Given the above, there has been an acknowledged need in the art to provide alternative precursors for deposition processes such as CVD and ALD that address the deficiencies of Mo(CO)₆. For example, Mo(PCl₂Me)(CO)₅ has been described as an attractive alternative due to its increased thermal stability. The thermal stability of Mo(PCl₂Me)(CO)₅ results from the presence of the chloro-phosphine which is an electron donor that accordingly (i) increases the electron density at the Mo center and (ii) which in turn increases the R-back donation to the CO ligands. The problem with Mo(PCl₂Me)(CO)₅ and similar materials, however, is that they contain chlorides which should generally be avoided in vapor deposition processes in order to avoid chlorine contamination of the as-deposited films.

Thus, there is a need for precursors that remedy the deficiencies of Mo(CO)₆ while also avoiding the contamination issues associated with Mo(PCl₂Me)(CO)₅ and similar materials and that remain suitable as CVD and ALD precursors. Preferably, such alternative precursors that can be preferably delivered in liquid phase, have low impurities and can produce a high-quality film with high conformality.

### SUMMARY

The disclosed and claimed subject matter relates to halogen-free molybdenum carbonyl compounds with phosphorus-based ligands having improved (i.e., higher) thermal stability and low melting point, compositions containing the compounds and methods of using the compounds as precursors for deposition of metal-containing films.

In one embodiment, the disclosed and claimed subject matter relates to compounds (and mixtures thereof) of Formula I-A, Formula I-B and I-C (collectively the “compounds of Formula I”):

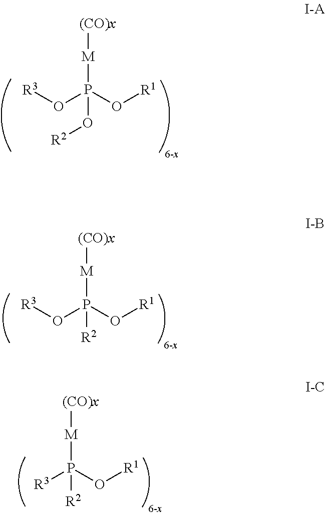

where (i) M is one of Mo, W and Cr, (ii) R¹ R² and R³ are each independently one of an unsubstituted linear C₁-C₈ alkyl group, an unsubstituted branched C₃-C₈ alkyl group, a linear or branched C₂-C₆ alkylene, a C₃-C₈ saturated cyclic alkyl and a C₅-C₈ arene and (iii) x=1, 2, 3, 4 or 5. Significantly, the disclosed and claimed compounds are substantially free or free of halogens (i.e., none of R¹, R² or R³ includes a halogen) and other materials that compromise the use of the precursors in CVD and ALD applications. More specific aspects and embodiments of compounds of Formula I are detailed below.

The disclosed and claimed subject further includes (i) compositions and formulations that include compounds of Formula I, (ii) methods of using the disclosed and claimed compounds of Formula I in deposition processes and (iii) metal-containing films derived from the disclosed and claimed compounds of Formula I produced in deposition processes.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates an exemplary target of selective deposition processes where metal film is selectively deposited on conductive film, while dielectric film is passivated; and

FIG. 2 illustrates an exemplary target of selective deposition processes where dielectric film is selectively deposited on dielectric film, while metal surface is passivated; and

FIG. 3 illustrates the thermogravimetric analysis (TGA) of an exemplary precursor of the disclosed and claimed subject matter from Example 1 (trimethylphosphite pentacarbonyl molybdenum).

FIG. 4 illustrates the differential scanning calorimetry (DSC) of an exemplary precursor of the disclosed and claimed subject matter from Example 1 (trimethylphosphite pentacarbonyl molybdenum).

FIG. 5 illustrates the ¹H NMR spectrum of an exemplary precursor of the disclosed and claimed subject matter from Example 1 (trimethylphosphite pentacarbonyl molybdenum).

FIG. 6 illustrates the ¹³C NMR spectrum of an exemplary precursor of the disclosed and claimed subject matter from Example 1 (trimethylphosphite pentacarbonyl molybdenum).

FIG. 7 illustrates the ³¹P NMR spectrum of an exemplary precursor of the disclosed and claimed subject matter from Example 1 (trimethylphosphite pentacarbonyl molybdenum).

### DETAILED DESCRIPTION

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. The use of the term “comprising” or “including” in the specification and the claims includes the narrower language of “consisting essentially of” and “consisting of.”

Embodiments of the disclosed and claimed subject matter are described herein, including the best mode known to the inventors for carrying out the disclosed and claimed subject matter. Variations of those embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, the disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

The term “alkylene” refers an alkylene linkage between (i) one carbon atom in a cyclopentadienyl (“Cp”) group and (ii) O or N atoms, preferably, C₁₋₄ alkylene linkages such as an ethylene bridge. Specific examples of the alkylene linkages include methylene (—CH₂—), ethylene (—CH₂CH₂—), substituted ethylenes, (e.g., —CH(CH₃)CH₂—; —CH(CH₃)CH(CH₃)—; —C(CH₃)₂CH₂—), propylene (—CH₂CH₂CH₂—) and substituted propylenes.

The term “arene” refers to aromatic organic compounds containing solely carbon and hydrogen atoms.

It will be understood that the term “silicon” as deposited as a material on a microelectronic device will include polysilicon.

For ease of reference, “microelectronic device” or “semiconductor device” corresponds to semiconductor wafers having integrated circuits, memory, and other electronic structures fabricated thereon, and flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” or “semiconductor device” is not meant to be limiting in any way and includes any substrate that will eventually become a microelectronic device or microelectronic assembly.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 0.001 wt. %. “Substantially free” also includes 0.000 wt. %. The term “free of” means 0.000 wt. %. As used herein, “about” or “approximately” are intended to correspond to within ±5% of the stated value.

In all such compositions, wherein specific components of the composition are discussed in reference to weight percentage (or “weight %”) ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all percentages of the components are weight percentages and are based on the total weight of the composition, that is, 100%. Any reference to “one or more” or “at least one” includes “two or more” and “three or more” and so on.

Where applicable, all weight percents unless otherwise indicated are “neat” meaning that they do not include the aqueous solution in which they are present when added to the composition. For example, “neat” refers to the weight % amount of an undiluted acid or other material (i.e., the inclusion 100 g of 85% phosphoric acid constitutes 85 g of the acid and 15 grams of diluent).

Moreover, when referring to the compositions described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the formulation can contain 2% by weight or less of impurities. In another embodiment, the formulation can contain 1% by weight or less than of impurities. In a further embodiment, the formulation can contain 0.05% by weight or less than of impurities. In other such embodiments, the constituents can form at least 90 wt %, more preferably at least 95 wt %, more preferably at least 99 wt %, more preferably at least 99.5 wt %, most preferably at least 99.9 wt %, and can include other ingredients that do not material affect the performance of the wet etchant. Otherwise, if no significant non-essential impurity component is present, it is understood that the composition of all essential constituent components will essentially add up to 100 weight %.

The headings employed herein are not intended to be limiting; rather, they are included for organizational purposes only.

### EXEMPLARY EMBODIMENTS

In one embodiment, the disclosed and claimed subject matter relates to compounds (and mixtures thereof) of Formula I-A, Formula I-B and I-C(collectively the “compounds of Formula I”):

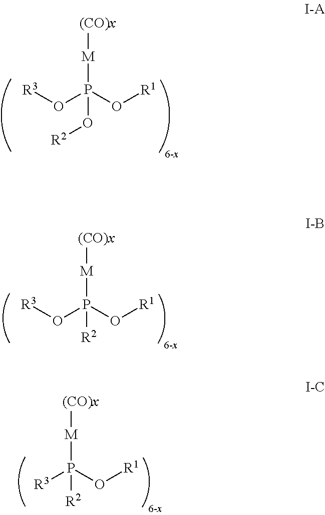

where (i) M is one of Mo, W and Cr, (ii) R¹ R² and R³ are each independently one of an unsubstituted linear C₁-C₈ alkyl group, an unsubstituted branched C₃-C₈ alkyl group, a linear or branched C₂-C₆ alkylene, a C₃-C₈ saturated cyclic alkyl and a C₅-C₈ arene and (iii) x=1, 2, 3, 4 or 5.

In one aspect of this embodiment, M is molybdenum (Mo). In another aspect of this embodiment, M is tungsten (W). In another aspect of this embodiment, M is chromium (Cr).

In one aspect of this embodiment, the compound includes, consists essentially of or consists of one or more compound of Formula I-A. In one aspect of this embodiment, the compound includes, consists essentially of or consists of one or more compound of Formula I-B. In one aspect of this embodiment, the compound includes, consists essentially of or consists of one or more compound of Formula I-C. In one aspect of this embodiment, the compound includes, consists essentially of or consists of a mixture of two or more of a compound of Formula I-A, a compound Formula of I-B and a compound of Formula of I-C. In one aspect of this embodiment, the compound of includes, consists essentially of or consists of a mixture of one or more compound of each of Formula I-A, a compound of Formula I-B and a compound of Formula I-C.

In one aspect of this embodiment, one or more of R¹, R² and R³ is each independently an unsubstituted linear C₁-C₈ alkyl group. In another aspect of this embodiment, one or more of R¹, R² and R³ is each independently a methyl group. In another aspect of this embodiment, one or more of R¹, R² and R³ is each independently an ethyl group. In another aspect of this embodiment, one or more of R¹, R² and R³ is each independently a propyl group. In another aspect of this embodiment, one or more of R¹, R² and R³ is each independently a butyl group. In another aspect of this embodiment, one or more of R¹, R² and R³ is each independently a pentyl group. In another aspect of this embodiment, one or more of R¹, R² and R³ is each independently a hexyl group. In another aspect of this embodiment, one or more of R¹, R² and R³ is each independently a heptyl group. In another aspect of this embodiment, one or more of R¹, R² and R³ is each independently an octyl group.

In one aspect of this embodiment, one or more of R¹, R² and R³ is each independently an unsubstituted branched C₃-C₈ alkyl group. In another aspect of this embodiment, one or more of R¹, R² and R³ is each independently an isopropyl group. In another aspect of this embodiment, one or more of R¹, R² and R³ is each independently a sec-butyl group. In another aspect of this embodiment, one or more of R¹, R² and R³ is each independently an iso-butyl group. In another aspect of this embodiment, one or more of R¹, R² and R³ is each independently a tert-butyl group. In another aspect of this embodiment, one or more of R¹, R² and R³ is each independently a tert-pentyl group.

In one aspect of this embodiment, one or more of R¹, R² and R³ is each independently a linear or branched C₂-C₆ alkylene. In another aspect of this embodiment, one or more of R¹, R² and R³ is each independently an ethylene group. In another aspect of this embodiment, one or more of R¹, R² and R³ is each independently a 1-propylene group. In another aspect of this embodiment, one or more of R¹, R² and R³ is each independently a 2-propylene group.

In one aspect of this embodiment, one or more of R¹, R² and R³ is each independently a C₃-C₈ saturated cyclic alky. In another aspect of this embodiment, one or more of R¹, R² and R³ is each independently a C₃ saturated cyclic alky. In another aspect of this embodiment, one or more of R¹, R², R³ is each independently a C₄ saturated cyclic alky. In another aspect of this embodiment, one or more of R¹, R² and R³ is each independently a C₅ saturated cyclic alky. In another aspect of this embodiment, one or more of R¹, R² and R³ is each independently a C₆ saturated cyclic alky. In another aspect of this embodiment, one or more of R¹, R² and R³ is each independently a C₇ saturated cyclic alky. In another aspect of this embodiment, one or more of R¹, R² and R³ is each independently a C₈ saturated cyclic alky.

In one aspect of this embodiment, one or more of R¹, R² and R³ is each independently a C₅-C₈ arene. In another aspect of this embodiment, one or more of R¹, R² and R³ is each independently a C₃ arene. In another aspect of this embodiment, one or more of R¹, R² and R³ is each independently a C₄ arene. In another aspect of this embodiment, one or more of R¹, R² and R³ is each independently a C₅ arene. In another aspect of this embodiment, one or more of R¹, R² and R³ is each independently a C₆ arene. In another aspect of this embodiment, R¹ is a C₇ arene. In another aspect of this embodiment, one or more of R¹, R² and R³ is each independently a C₈ arene.

In one aspect of this embodiment, R²=R¹. In another aspect of this embodiment, R² is different than R¹.

In one aspect of this embodiment, R³=R¹. In another aspect of this embodiment, R³ is different than R¹.

In one aspect of this embodiment, R²=R³. In another aspect of this embodiment, R² is different than R³.

In one aspect of this embodiment, R¹=R²=R³. In another aspect of this embodiment, two of R¹, R² and R³ are the same. In another aspect of this embodiment, each of R¹, R² and R³ are different from one another.

In one aspect of this embodiment, x=1. In one aspect of this embodiment, x=2. In one aspect of this embodiment, x=3. In one aspect of this embodiment, x=4. In one aspect of this embodiment, x=5.

In one aspect of this embodiment, the compound includes a compound of Formula I-A where M is molybdenum (Mo) and each of R¹, R² and R³ is a methyl group. In one aspect of this embodiment, the compound includes a compound of Formula I-B where M is molybdenum (Mo) and each of R¹, R² and R³ is a methyl group. In one aspect of this embodiment, the compound includes a compound of Formula I-C where M is molybdenum (Mo) and each of R¹, R² and R³ is a methyl group. In another aspect of each of the above, x=5.

In one aspect of this embodiment, the compound includes a compound of Formula I-A where M is tungsten (W) and each of R¹, R² and R³ is a methyl group. In one aspect of this embodiment, the compound includes a compound of Formula I-B where M is tungsten (W) and each of R¹, R² and R³ is a methyl group. In one aspect of this embodiment, the compound of includes a compound of Formula I-C where M is tungsten (W) and each of R¹, R² and R³ is a methyl group. In another aspect of each of the above, x=5.

In one aspect of this embodiment, the compound includes a compound of Formula I-A where M is chromium (Cr) and each of R¹, R² and R³ is a methyl group. In one aspect of this embodiment, the compound includes a compound of Formula I-B where M is chromium (Cr) and each of R¹, R² and R³ is a methyl group. In one aspect of this embodiment, the compound includes a compound of Formula I-C where M is chromium (Cr) and each of R¹, R² and R³ is a methyl group. In another aspect of each of the above, x=5.

In one aspect of this embodiment, the compound includes a compound of Formula I-A where M is molybdenum (Mo) and each of R¹, R² and R³ is an ethyl group. In one aspect of this embodiment, the compound includes a compound of Formula I-B where M is molybdenum (Mo) and each of R¹, R² and R³ is an ethyl group. In one aspect of this embodiment, the compound includes a compound of Formula I-C where M is molybdenum (Mo) and each of R¹, R² and R³ is an ethyl group. In another aspect of each of the above, x=5.

In one aspect of this embodiment, the compound includes a compound of Formula I-A where M is tungsten (W) and each of R¹, R² and R³ is an ethyl group. In one aspect of this embodiment, the compound includes a compound of Formula I-B where M is tungsten (W) and each of R¹, R² and R³ is an ethyl group. In one aspect of this embodiment, the compound of includes a compound of Formula I-C where M is tungsten (W) and each of R¹, R² and R³ is an ethyl group. In another aspect of each of the above, x=5.

In one aspect of this embodiment, the compound includes a compound of Formula I-A where M is chromium (Cr) and each of R¹, R² and R³ is an ethyl group. In one aspect of this embodiment, the compound includes a compound of Formula I-B where M is chromium (Cr) and each of R¹, R² and R³ is an ethyl group. In one aspect of this embodiment, the compound of includes a compound of Formula I-C where M is chromium (Cr) and each of R¹, R² and R³ is an ethyl group. In another aspect of each of the above, x=5.

In one aspect of this embodiment, the compound includes a compound of Formula I-A where M is molybdenum (Mo) and each of R¹, R² and R³ is a propyl group. In one aspect of this embodiment, the compound includes a compound of Formula I-B where M is molybdenum (Mo) and each of R¹, R² and R³ is a propyl group. In one aspect of this embodiment, the compound includes a compound of Formula I-C where M is molybdenum (Mo) and each of R¹, R² and R³ is a propyl group. In another aspect of each of the above, x=5.

In one aspect of this embodiment, the compound includes a compound of Formula I-A where M is tungsten (W) and each of R¹, R² and R³ is a propyl group. In one aspect of this embodiment, the compound includes a compound of Formula I-B where M is tungsten (W) and each of R¹, R² and R³ is a propyl group. In one aspect of this embodiment, the compound includes a compound of Formula I-C where M is tungsten (W) and each of R¹, R² and R³ is a propyl group. In another aspect of each of the above, x=5.

In one aspect of this embodiment, the compound includes a compound of Formula I-A where M is chromium (Cr) and each of R¹, R² and R³ is a propyl group. In one aspect of this embodiment, the compound includes a compound of Formula I-B where M is chromium (Cr) and each of R¹, R² and R³ is a propyl group. In one aspect of this embodiment, the compound includes a compound of Formula I-C where M is chromium (Cr) and each of R¹, R² and R³ is a propyl group.

Preferred compounds of Formula I (i.e., compounds of Formula I-A, Formula I-B and Formula I-C) are those exemplified in Tables 1-3. It is to be understood, however, that the compounds of Formula I included in disclosed and claimed subject matter is not limited to the compounds of Formula I exemplified in Tables 1-3.

TABLE 1
Compound of Formula I

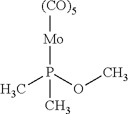

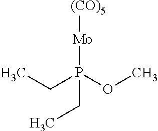

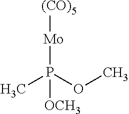

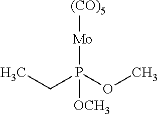

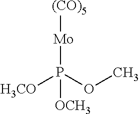

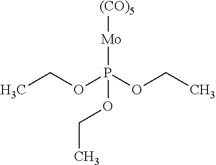

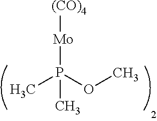

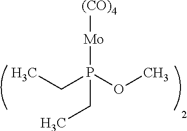

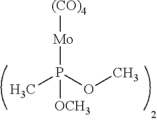

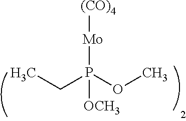

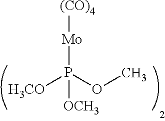

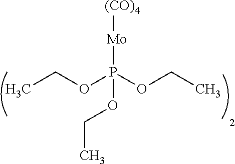

M = Molybdenum (Mo)

TABLE 2
Compound of Formula I

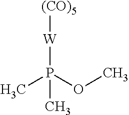

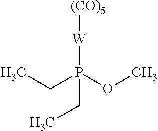

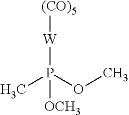

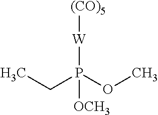

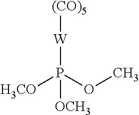

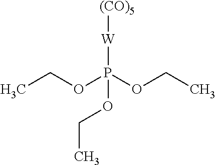

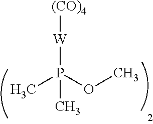

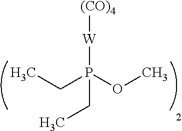

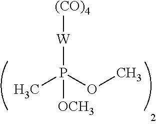

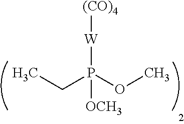

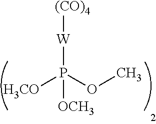

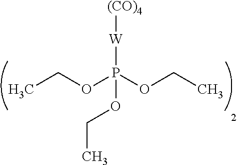

M = Tungsten (W)

TABLE 3
Compound of Formula I

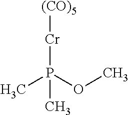

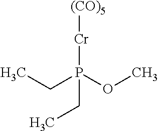

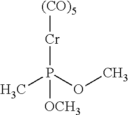

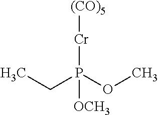

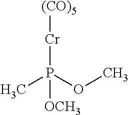

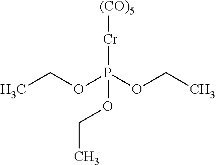

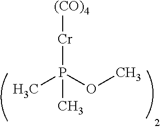

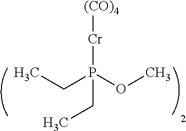

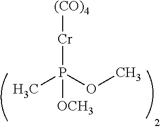

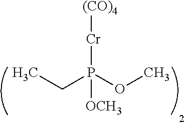

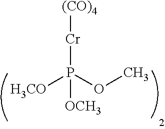

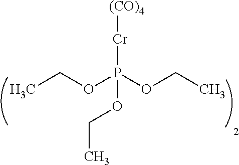

M = Chromium (Cr)

### Method of Use

The disclosed precursors may be deposited to form metal-containing films (particularly a molybdenum-containing films) using any chemical vapor deposition process known to those of skill in the art. As used herein, the term “chemical vapor deposition process” refers to any process wherein a subst^{ra}te is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits films of materials onto substrates of varying compositions. Although the precursors, reagents and sources used herein may be sometimes described as “gaseous,” it is understood that the precursors can be either liquid or solid which are transported with or without an inert gas into the reactor via direct vaporization, bubbling or sublimation. In some case, the vaporized precursors can pass through a plasma generator. The term “reactor” as used herein, includes without limitation, reaction chamber, reaction vessel or deposition chamber.

The disclosed and claimed chemical vapor deposition processes include vaporizing at least one organometallic complex corresponding in structure to Formula I as disclosed herein. For example, this may include vaporizing the at least one complex and delivering the at least one complex to a substrate surface or passing the at least one complex over a substrate and/or decomposing the at least one complex on the substrate surface.

In one embodiment, the organometallic complexes may be dissolved in an appropriate hydrocarbon or amine solvent. Appropriate hydrocarbon solvents include, but are not limited to aliphatic hydrocarbons, such as hexane, heptane, and nonane; aromatic hydrocarbons, such as toluene and xylene; aliphatic and cyclic ethers, such as diglyme, triglyme, and tetraglyme. Examples of appropriate amine solvents include, without limitation, octylamine and N,N-dimethyldodecylamine. For example, the organometallic complex may be dissolved in toluene to yield a solution with a concentration of about 50 mM to about 1 M.

The compounds of The Formula I may be liquid, solid, or gaseous when utilized in these methods. Typically, the compounds are liquid or a low-melting solid at ambient temperatures with a vapor pressure sufficient to allow for consistent transport of the vapor to the process chamber. In another embodiment, at least one complex corresponding in structure to Formula may be delivered “neat” (undiluted by a carrier gas) to a substrate. In one embodiment, the compounds of Formula I is a solid with a melting point less than or equal to about 50° C., less than or equal to about 45° C., less than or equal to about 40° C., less than or equal to about 35° C., or less than or equal to about 30° C.

The disclosed and claimed ALD and CVD methods encompass various types of ALD and CVD processes such as, but not limited to, continuous or pulsed injection processes, liquid injection processes, photo-assisted processes, and plasma-assisted processes Thus, the chemical vapor deposition processes in which the disclosed and claimed compounds can be utilized include, but are not limited to, those used for the manufacture of semiconductor type microelectronic devices such as ALD, CVD, pulsed CVD, plasma enhanced ALD (PEALD) and/or plasma enhanced CVD (PECVD). Examples of suitable deposition processes for the method disclosed herein include, but are not limited to, cyclic CVD (CCVD), MOCVD (Metal Organic CVD), thermal chemical vapor deposition, plasma enhanced chemical vapor deposition (“PECVD”), high density PECVD, photon assisted CVD, plasma-photon assisted (“PPECVD”), cryogenic chemical vapor deposition, chemical assisted vapor deposition, hot-filament chemical vapor deposition, CVD of a liquid polymer precursor, deposition from supercritical fluids, and low energy CVD (LECVD). In certain embodiments, the metal containing films are deposited via atomic layer deposition (ALD), plasma enhanced ALD (PEALD) or plasma enhanced cyclic CVD (PECCVD) process. For purposes of clarity, the methods of the present invention specifically include direct liquid injection processes. For example, in direct liquid injection CVD) (“DLI-CVD”), a solid or liquid complex may be dissolved in a suitable solvent and the solution formed therefrom injected into a vaporization chamber as a means to vaporize the complex. The vaporized complex is then transported/delivered to the substrate. In general, DLI-CVD may be particularly useful in those instances where a complex displays relatively low volatility or is otherwise difficult to vaporize.

Suitable substrates on which the disclosed and claimed compounds can be deposited are not particularly limited and vary depending on the final use intended. For example, the substrate may be chosen from oxides such as HfO₂-based materials, TiO₂-based materials, ZrO₂-based materials, rare earth oxide-based materials, ternary oxide-based materials, etc. or from nitride-based films. Other substrates may include solid substrates such as metal substrates (e.g., Au, Pd, Rh, Ru, W, Al, Ni, Ti, Co, Pt and metal silicides (e.g., TiSi₂, CoSi₂, and NiSi₂); metal nitride containing substrates (e.g., TaN, TiN, WN, TaCN, TiCN, TaSiN, and TiSiN); semiconductor materials (e.g., Si, SiGe, GaAs, InP, diamond, GaN, and SiC); insulators (e.g., SiO₂, Si₃N₄, SiON, HfO₂, Ta₂O₅, ZrO₂, TiO₂, Al₂O₃, and barium strontium titanate); combinations thereof. Preferred substrates include TiN, Ru and Si type substrates.

In such deposition methods and processes an oxidizing agent can be utilized. The oxidizing agent is typically introduced in gaseous form. Examples of suitable oxidizing agents include, but are not limited to, oxygen gas, water vapor, ozone, oxygen plasma, or mixtures thereof.

The deposition methods and processes may also involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, and mixtures thereof. For example, a purge gas such as Ar is supplied into the reactor at a flow rate ranging from about 10 to about 2000 sccm for about 0.1 to 10000 seconds, thereby purging the unreacted material and any byproduct that may remain in the reactor.

The deposition methods and processes require that energy be applied to the at least one of the precursors, oxidizing agent, other precursors or combination thereof to induce reaction and to form the metal-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In some processes, a secondary RF frequency source can be used to modify the plasma characteristics at the substrate surface. When utilizing plasma, the plasma-generated process may include a direct plasma-generated process in which plasma is directly generated in the reactor, or alternatively a remote plasma-generated process in which plasma is generated outside of the reactor and supplied into the reactor.

When utilized in such deposition methods and processes suitable compounds—such as those presently disclosed and claimed—may be delivered to the reaction chamber such as a CVD or ALD reactor in a variety of ways. In some instances, a liquid delivery system may be utilized. In other instances, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. The precursor compositions described herein can be effectively used as source reagents via direct liquid injection (DLI) to provide a vapor stream of these metal precursors into an ALD or CVD reactor.

When used in these deposition methods and processes, the disclosed and claimed compounds include hydrocarbon solvents which are particularly desirable due to their ability to be dried to sub-ppm levels of water. Exemplary hydrocarbon solvents that can be used in the precursors include, but are not limited to, toluene, mesitylene, cumene (isopropylbenzene), p-cymene (4-isopropyl toluene), 1,3-diisopropylbenzene, octane, dodecane, 1,2,4-trimethylcyclohexane, n-butylcyclohexane, and decahydronaphthalene (decalin). The disclosed and claimed compounds can also be stored and used in stainless steel containers. In certain embodiments, the hydrocarbon solvent is a high boiling point solvent or has a boiling point of 100 degrees Celsius or greater. The disclosed and claimed compounds can also be mixed with other suitable metal precursors, and the mixture used to deliver both metals simultaneously for the growth of a binary metal-containing films.

A flow of argon and/or other gas may be employed as a carrier gas to help deliver a vapor containing at least one of the disclosed and claimed compounds to the reaction chamber during the precursor pulsing. When delivering the precursors, the reaction chamber process pressure is between 1 and 50 torr, preferably between 5 and 20 torr.

Substrate temperature can be an important process variable in the deposition of high-quality metal-containing films. Typical substrate temperatures range from about 150° C. to about 550° C. Higher temperatures can promote higher film growth rates.

In one embodiment, for example, a Mo, molybdenum nitride (e.g., MoN, Mo₂N, or MoN/Mo₂N), and/or a molybdenum oxide (e.g., MoO₂, MoO₃, or MoO₂/MoO₃) film can be formed by delivering for deposition at least one compound according to Formula I where M is molybdenum, independently or in combination with one or more co-reactant. The one or more co-reactant may be deposited or delivered or passed over a substrate, independently or in combination with the at least one complex Examples of such co-reactants include, but are not limited to hydrogen, hydrogen plasma, oxygen, air, water, H₂O₂, ammonia, a hydrazine, a borane, a silane, such as a trisilane, ozone or any combination thereof. Examples of suitable boranes include, without limitation, hydridic (i.e., reducing) boranes such as borane, diborane, triborane and the like. Examples of suitable silanes include, without limitation, hydridic silanes such as silane, disilane, trisilane, and the like. Examples of suitable hydrazines include, without limitation, hydrazine (N₂H₄) and/or a hydrazine optionally substituted with one or more alkyl groups (i.e., an alkyl-substituted hydrazine) such as methylhydrazine, tert-butylhydrazine, N,N- or N,N′-dimethylhydrazine, and the like. One of ordinary skill will appreciate that detailed descriptions of methods above involving molybdenum can be adjusted as necessary for other metals—e.g., where M is chromium or tungsten.

In a particular embodiment, one or more co-reactant is used to form a MoO₂, MoO₃, or MoO₂/MoO₃ film by delivering for deposition one or more compound according to Formula I where M is molybdenum, independently or in combination, with the one or more co-reactant such as, but not limited to air, H₂O, O₂, and/or ozone to a reaction chamber. A plurality of such co-reactants may be used One of ordinary skill will appreciate that detailed descriptions of methods above involving molybdenum can be adjusted as necessary for other metals—e.g., where M is chromium or tungsten.

In another particular embodiment, one or more co-reactant is used to form a MON, Mo₂N, or MoN/Mo₂N film by delivering for deposition one or more copound according to Formula I where M is molybdenum, independently or in combination, with the one or more co-reactant such as, but not limited to ammonia, a hydrazine, or other nitrogen-containing compound, such as but not limited to an amine, to a reaction chamber. A plurality of such co-reactants may be used One of ordinary skill will appreciate that detailed descriptions of methods above involving molybdenum can be adjusted as necessary for other metals—e.g., where M is chromium or tungsten.

In another particular embodiment, a co-reactant is used to form a molybdenum-containing metal film by delivering for deposition at least one complex according to Formula I where M is molybdenum, independently or in combination, with a co-reactant such as, but not limited to H₂, a hydrazine, a silane such as trisilane, and/or ammonia to a reaction chamber. One of ordinary skill will appreciate that detailed descriptions of methods above involving molybdenum can be adjusted as necessary for other metals—e.g., where M is chromium or tungsten.

### SPECIFIC EMBODIMENTS

In view of the forgoing, those skilled in the art will recognize that the disclosed and claimed subject matter further include the use of the disclosed and claimed compounds in chemical vapor deposition processes as follows.

In one embodiment, the disclosed and claimed subject matter includes a method for forming a transition metal-containing film on at least one surface of a substrate that includes the steps of
(i) providing the at least one surface of the substrate in a reaction vessel;
(ii) forming a transition metal-containing film on the at least one surface by a deposition process chosen from a chemical vapor deposition (CVD) process and an atomic layer deposition (ALD) process using one or the disclosed and claimed compounds of as a metal source compound for the deposition process.
   In a further aspect of this embodiment, the method includes introducing at least one reactant into the reaction vessel. In a further aspect of this embodiment, the method includes introducing at least one reactant into the reaction vessel where the at least one reactant is selected from the group of water, diatomic oxygen, oxygen plasma, ozone, NO, N₂O, NO₂, carbon monoxide, carbon dioxide and combinations thereof. In another aspect of this embodiment, the method includes introducing at least one reactant into the reaction vessel where the at least one reactant is selected from the group of ammonia, hydrazine, monoalkylhydrazine, dialkylhydrazine, nitrogen, nitrogen/hydrogen, ammonia plasma, nitrogen plasma, nitrogen/hydrogen plasma, and combinations thereof. In another aspect of this embodiment, the method includes introducing at least one reactant into the reaction vessel where the at least one reactant is selected from the group hydrogen, hydrogen plasma, a mixture of hydrogen and helium, a mixture of hydrogen and argon, hydrogen/helium plasma, hydrogen/argon plasma, boron-containing compounds, silicon-containing compounds and combinations thereof.

### CVD

In one embodiment, conventional or pulsed injection CVD is used to form a metal-containing thin film by vaporizing and/or passing at least one complex according to Formula I as disclosed herein over a substrate. For conventional and pulsed CVD processes, see. e.g., Smith, Donald. THIN-FILM DEPOSVTION: PRINCIPLES AND PRACTICE, McGraw-Hill (1995).

In view of the forgoing, those skilled in the art will recognize that the disclosed and claimed subject matter further includes the use of the disclosed and claimed formulations in a method of forming a transition metal-containing film on a substrate via an CVD process that includes the steps of:
(i) forming a metal-containing film on at least one surface of the substrate by contacting the at least one surface with one or more compounds of Formula 1 alone or optionally in conjunction with one or more co-reactants; and
(ii) optionally purging with an inert gas.
   In a further aspect of this embodiment, the method includes optionally passivating the at least one surface before step (i). In a further aspect of this embodiment, the method includes the one or more co-reactants is utilized and is one or more of water, diatomic oxygen, oxygen plasma, ozone, NO, N₂O, NO₂, carbon monoxide, carbon dioxide and combinations thereof. In a further aspect of this embodiment, the method includes the one or more co-reactants is utilized and is one or more of ammonia, hydrazine, monoalkylhydrazine, dialkylhydrazine, nitrogen, nitrogen/hydrogen, ammonia plasma, nitrogen plasma, nitrogen/hydrogen plasma, and combinations thereof. In a further aspect of this embodiment, the method includes the one or more co-reactants is utilized and is one or more of hydrogen, hydrogen plasma, a mixture of hydrogen and helium, a mixture of hydrogen and argon, hydrogen/helium plasma, hydrogen/argon plasma, boron-containing compounds, silicon-containing compounds and combinations thereof. In a further aspect, the compound of Formula I is introduced as a component of a vapor including one or more carrier gas.

In one aspect, the above-described CVD process utilizes, but is not limited to, one or more of the following growth conditions:
(1) Substrate temperature: 50-600° C. (e.g., 250-450° C., or even 300-350° C.),
(2) Evaporator temperature: 0-200° C.;
(3) Reactor pressure: 0-100 Torr (e.g., 0.5-10 Torr, or even 0.7-2 Torr);
(4) Purge gas flow rate: 0-500 sccm;
(5) O gas flow rate: 0-500 sccm;
(6) H gas flow rate: 0-500 sccm;
(7) Run time: will vary according to desired film thickness; and/or
(8) H gas:Mo precursor. Ratio≈2:1-10000:1 (e.g., 500.1-1000:1 or 5000.1-10000:1).

In another embodiment, photo-assisted CVD is used to form molybdenum-containing thin film by vaporizing and/or passing at least one molybdenum complex according to Formula I as disclosed herein over a substrate.

### ALD

In one embodiment, ALD is used to form a metal-containing thin film by vaporizing and/or passing at least one complex according to Formula I as disclosed herein over a substrate. In one aspect, conventional (i.e., pulsed injection) ALD is used to form a metal-containing thin film by vaporizing and/or passing at least one complex according to Formula I as disclosed herein over a substrate. For conventional ALD processes see, e.g., George et al, J. Phys. Chem. 100: 13121-31 (1996). In another aspect, liquid injection ALD is used to form a metal-containing thin film, e.g., a molybdenum film, by vaporizing and/or passing at least one complex according to Formula I as disclosed herein over a substrate, wherein at least one liquid complex is delivered to the reaction chamber by direct liquid injection as opposed to vapor draw by a bubbler. For liquid injection ALD process see, e.g., Potter et al., Chem. Vap. Deposition 11 (3): 159-69 (2005).

In one embodiment, the disclosed and claimed subject matter includes a method of forming a transition metal-containing film on a substrate via an ALD process or ALD-like process that includes the steps of:
(i) contacting a substrate with one or more of the disclosed and claimed compounds of Formula I;
(ii) purging any unreacted compounds Formula I with inert gas;
(iii) contacting the substrate with at least one co-reactant (e.g., a nitrogen source to form a metal nitride or an oxygen source to form a metal oxide) in the deposition reactor; and
(iv) optionally purging of any unreacted co-reactant containing reactant with inert gas.
   In a further aspect of this embodiment, the method consists essentially of steps (i), (ii), (iii) and (iv). In a further aspect of this embodiment, the method consists of steps (i), (ii), (iii) and (iv). The process can further optionally include (v) treating the substrate with plasma (e.g., nitrogen plasma, hydrogen plasma) to remove residual impurities. Thus, in a further aspect of this embodiment, the method consists essentially of steps (i), (ii), (iii), (iv) and (v). In a further aspect of this embodiment, the method consists of steps (i), (ii), (iii), (iv) and (v). As those skilled in the art will recognize, the above steps can be repeated until a desired thickness of the metal-containing film is obtained. In a further aspect of this embodiment, the co-reactant source gas is one or more of an oxygen-containing source gas selected from water, diatomic oxygen, oxygen plasma, ozone, NO, N₂O, NO₂, carbon monoxide, carbon dioxide and combinations thereof. In another aspect of this embodiment, the co-reactant source gas is one or more of a nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma and mixture thereof. In a further aspect of this embodiment, the method the first and second purge gases are each independently selected one or more of argon, nitrogen, helium, neon, and combinations thereof. In a further aspect of this embodiment, the method further includes applying energy to at least one of the precursor, the source gas, the substrate, and combinations thereof, wherein the energy is one or more of thermal, plasma, pulsed plasma, helicon plasma, high density plasma, inductively coupled plasma, X-ray, e-beam, photon, remote plasma methods and combinations thereof. In a further aspect of this embodiment, step b of the method further includes introducing into the reaction vessel the precursor using a stream of carrier gas to deliver a vapor of the precursor into the reaction vessel. In a further aspect of this embodiment, step b of the method further includes use of a solvent medium comprising one or more of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

In one aspect, the above-described ALD process utilizes, but is not limited to, one or more of the following growth conditions:
(1) Substrate temperature. 0-400° C.
(2) Evaporator (metal source) temperature: 0-200° C.,
(3) Reactor pressure: 0-100 Torr;
(4) Purge gas flow rate: 0-500 sccm;
(5) Reactive gas flow rate. 0-500 sccm;
(6) Pulse sequence (sec.): The time for each step of the complex/purge/reactive gas/purge cycle varies according to chamber size; and/or
(7) Number of cycles: Varies according to desired film thickness.

### Delivery of Compound(s) of Formula I

As noted above, step (i) of the disclosed and claimed method includes contacting a substrate with one or more of the disclosed and claimed compounds of Formula I.

In another embodiment, the one or more of the disclosed and claimed compounds of Formula I is supplied in vapor form for a period of time (i.e., the pulse time). In another embodiment, the one or more of the disclosed and claimed compounds of Formula I pulse time is from about 0.1 seconds to about 3 seconds. In another embodiment, the one or more of the disclosed and claimed compounds of Formula I vapor pulse time is from about 0.3 seconds to about 3 seconds. In another embodiment, the one or more of the disclosed and claimed compounds of Formula I vapor pulse time is about 0.1 second. In another embodiment, the one or more of the disclosed and claimed compounds of Formula I vapor pulse time is about 0.25 second. In another embodiment, the one or more of the disclosed and claimed compounds of Formula I vapor pulse time is about 0.5 second. In another embodiment, the one or more of the disclosed and claimed compounds of Formula I vapor pulse time is about 1 second. In another embodiment, the one or more of the disclosed and claimed compounds of Formula I vapor pulse time is about 1.5 seconds. In another embodiment, the one or more of the disclosed and claimed compounds of Formula I vapor pulse time is about 2 seconds.

In one embodiment, the one or more of the disclosed and claimed compounds of Formula I vapor is separated from other precursor materials prior to and/or during the introduction to the reactor. This process avoids pre-reaction of the metal precursor with any other materials.

In another embodiment, the one or more of the disclosed and claimed compounds of Formula I vapor is alternatively exposed to the substrate with other reactants (e.g., ammonia vapor, and/or other precursors or co-reactants). This process enables film growth to proceed by self-limiting control of the surface reactions, the pulse length of each precursor or reagent and the deposition temperature. It should be noted, however, that film growth ceases once the surface of the substrate is saturated with vanadium oxytrichloride one or more of the disclosed and claimed compounds of Formula I vapor.

In another embodiment, a flow of argon and/or other gas is employed as a carrier gas to help deliver the vapor of the one or more of the disclosed and claimed compounds of Formula I to the reaction reactor during the precursor pulsing.

### Purging Step

As noted above, step (ii) of the disclosed and claimed method includes purging any unreacted compounds of Formula I with inert gas. Purging with an inert gas removes unabsorbed excess complex from the process reactor.

In one embodiment, for example, the purge time varies from about 1 seconds to about 90 seconds. In one embodiment, for example, the purge time varies from about 15 seconds to about 90 seconds. In one embodiment, for example, the purge time varies from about 15 seconds to about 60 seconds. In another embodiment, the purge time is about 30 seconds. In another embodiment, the purge time is about 60 seconds. In another embodiment, the purge time is about 90 seconds.

In one embodiment, the purge gas includes argon. In another embodiment, the purge gas includes nitrogen.

### Co-Reactant Treatment

As noted above, step (iii) of the disclosed and claimed method includes contacting the substrate with at least one co-reactant (e.g., a nitrogen source to form a metal nitride or an oxygen source to form a metal oxide) in the deposition reactor.

In one embodiment, the co-reactant includes a nitrogen source that includes one or more of nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma. In another embodiment, the nitrogen source includes ammonia gas. In one embodiment, for example, the nitrogen source pulse time varies from about 0.5 seconds to about 5 seconds. In one embodiment, for example, the nitrogen source pulse time is about 2.5 seconds. In one embodiment, for example, the nitrogen source pulse time is about 5 seconds.

In one embodiment, the co-reactant includes an oxygen source that includes one or more of water, diatomic oxygen, oxygen plasma, ozone, NO, N₂O, NO₂, carbon monoxide, carbon dioxide and combinations thereof. In one embodiment, for example, the oxygen source pulse time varies from about 0.5 seconds to about 5 seconds. In one embodiment, for example, the oxygen source pulse time is about 2.5 seconds. In one embodiment, for example, the oxygen source pulse time is about 5 seconds.

### Optional Co-Reactant Purging Step

As noted above, step (iv) of the disclosed and claimed method includes optionally purging of any unreacted co-reactant with inert gas. Purging with an inert gas removes any remaining co-reactant from the process reactor. In one embodiment, the purge gas includes argon. In another embodiment, the purge gas includes nitrogen. As those skilled in the art will recognize, in many instances, if not in most instances, the disclosed and claimed process will include the step of purging the unreacted co-reactant. One exception may be where a nitrogen co-reactant is used and is not purged but is instead relied upon as a nitrogen source for a subsequent plasma treatment (described below).

In one embodiment, for example, the optional co-reactant purge time varies from about 15 seconds to about 90 seconds. In one embodiment, for example, the optional co-reactant purge time varies from about 15 seconds to about 60 seconds. In another embodiment, the optional co-reactant purge time is about 30 seconds. In another embodiment, the optional co-reactant purge time is about 60 seconds. In another embodiment, the optional co-reactant purge time is about 90 seconds.

### Optional Plasma Treatment

As noted above, step (v) of the disclosed and claimed method includes substrate treatment with nitrogen plasma or hydrogen plasma to remove residual impurities formed during the previous steps.

In one embodiment, the use of plasma constitutes a direct plasma-generated process in which plasma is directly generated in the reactor. In another embodiment, the use of plasma constitutes a remote plasma-generated process in which plasma is generated outside of the reactor and supplied into the reactor. In this regard, and as noted above, when the plasma source relies on a material that is also used as a co-reactant (e.g., ammonia as the nitrogen source), the optional co-reactant purge step (iv) can be omitted. When nitrogen plasma is utilized, the nitrogen source can include nitrogen (N₂), ammonia, hydrazine, monoalkylhydriazine, dialkylhydrazine.

### Operating Conditions

As noted above, the disclosed and claimed vanadium deposition process can be effectively conducted under very favorable ALD conditions to provide highly conformal films of vanadium nitride.

In one embodiment the substrate (e.g., a silicon oxide, aluminum oxide (Al₂O₃), titanium nitride (TiN), silicon oxide (SiO₂) and zirconium oxide (ZrO₂ is heated on a heater stage in a reaction reactor that is exposed to vanadium oxytrichloride precursor initially to allow the complex to chemically adsorb onto the surface of the substrate. In one embodiment, the substrate temperature is from about 300° C. to about 600° C. In a further aspect of this embodiment, the substrate temperature is from about 350° C. to about 550° C. In a further aspect of this embodiment, the substrate temperature is from about 400° C. to about 500° C.

In another embodiment, the reactor pressure for depositions according to the disclosed and claimed process is ≤about 50 torr. In another embodiment, the reactor pressure for depositions according to the disclosed and claimed process is ≤about 40 torr. In another embodiment, the reactor pressure for depositions according to the disclosed and claimed process is ≤about 30 torr. In a further aspect of this embodiment, the reactor pressure is ≤about 20 torr. In a further aspect of this embodiment, the reactor pressure is ≤about 10 torr. In a further aspect of this embodiment, the reactor pressure is ≤about 5 torr.

### Cycles and Order of Steps

In the above-described embodiments, as well as the other embodiments described herein, the described steps (e.g., (i) through (iv) or (i) through (v)) define one cycle of the method. It is to be understood that a cycle can be repeated until the desired thickness of a film is obtained.

In the embodiments described herein, it is understood that the steps of the methods may be performed in a variety of orders, may be performed sequentially or concurrently (e.g., during at least a portion of another step), and any combination thereof. In addition, the respective step of supplying the one or more of the disclosed and claimed compounds of Formula I and co-reactant source may be performed by varying the duration of the time for supplying them to change film composition.

In one embodiment, the disclosed and claimed subject matter includes films deposited by the above methods and using the disclosed and claimed compounds of Formula I. In one aspect of this embodiment, the films deposited by the above methods and using the disclosed and claimed compounds of Formula I have a resistivity below approximately 500 μOhm cm. In another aspect of this embodiment, the films deposited by the above methods and using the disclosed and claimed compounds of Formula I have a resistivity below approximately 400 μOhm cm. In another aspect of this embodiment, the films deposited by the above methods and using the disclosed and claimed compounds of Formula I have a resistivity below approximately 300 μOhm cm. In another aspect of this embodiment, the films deposited by the above methods and using the disclosed and claimed compounds of Formula I have a resistivity below approximately 200 μOhm cm. In another aspect of this embodiment, the films deposited by the above methods and using the disclosed and claimed compounds of Formula I have a resistivity below approximately 100 μOhm cm.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

All manipulations were performed under an inert atmosphere of dry argon, using standard Schlenk and dry box techniques. Dry and oxygen-free solvents were purchased from Arcos and were degassed and stored over molecular sieves (3 and 4 Å) prior to use. All glassware was oven-dried at 120° C. prior to use. Reagents and Handling: [Mo(CO)₆] and trimethyl phosphite were purchased from Sigma Aldrich and used as received.

### Example 1

Trimethylphosphite pentacarbonyl molybdenum may be synthesized by well-known methods, such as those described in Brown and Darensbourg, Inorg. Chem., Vol. 7, No. 5 (1968).

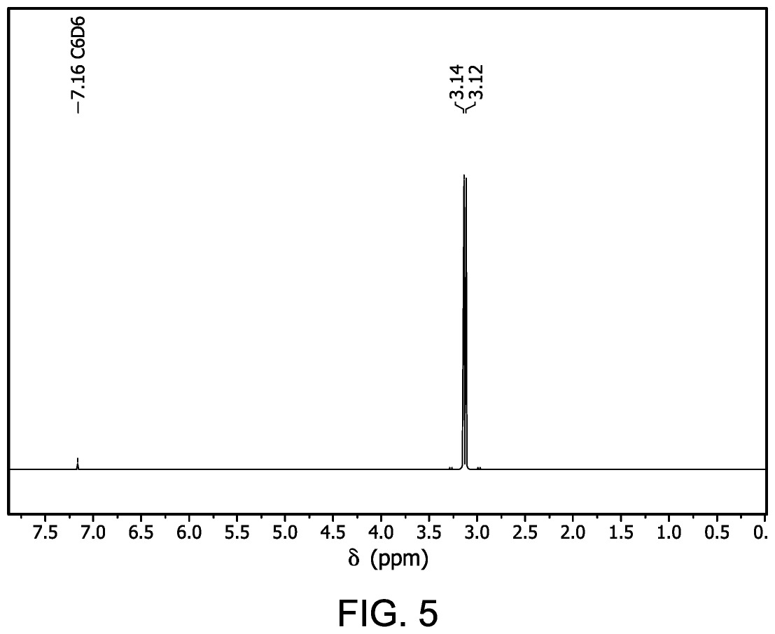

The trimethyl phosphite (1.41 g, 11.36 mmol) and [Mo(CO)₆](3.0 g, 11.36 mmol) were refluxed in toluene (50 mL) for 24 h. The reaction mixture turned into a brown slurry during this time. After 24 h the solvent of the reaction mixture was evaporated in vacuum. The desired complex was obtained as a colorless liquid after distillation (110° C., 1.0×10⁻² mbar). Yield: 72%. Purity: >99% (as shown in FIG. 5).

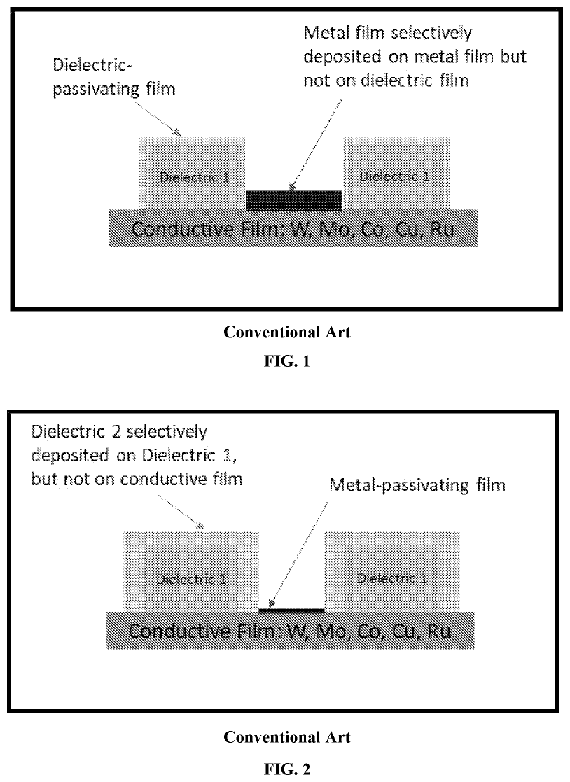

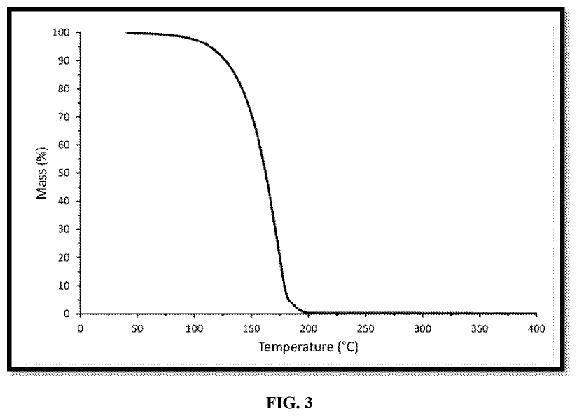

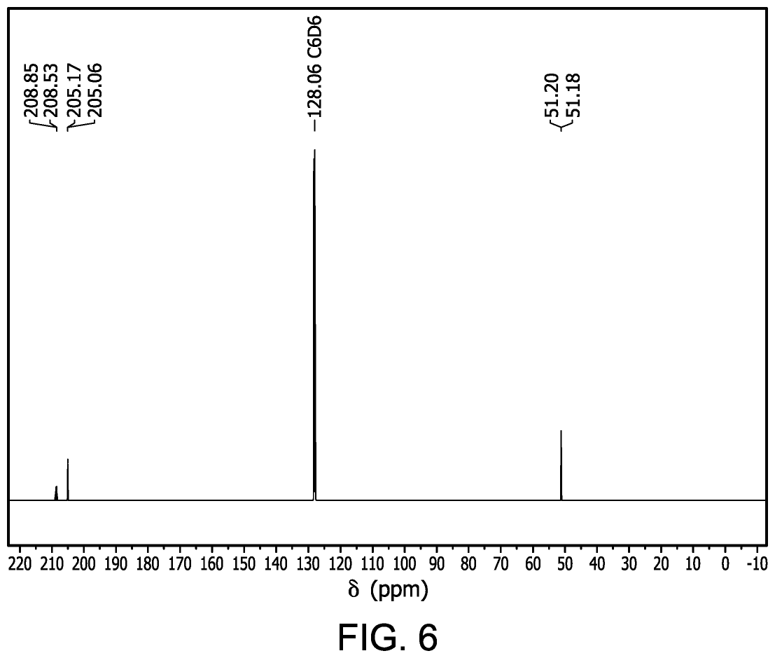

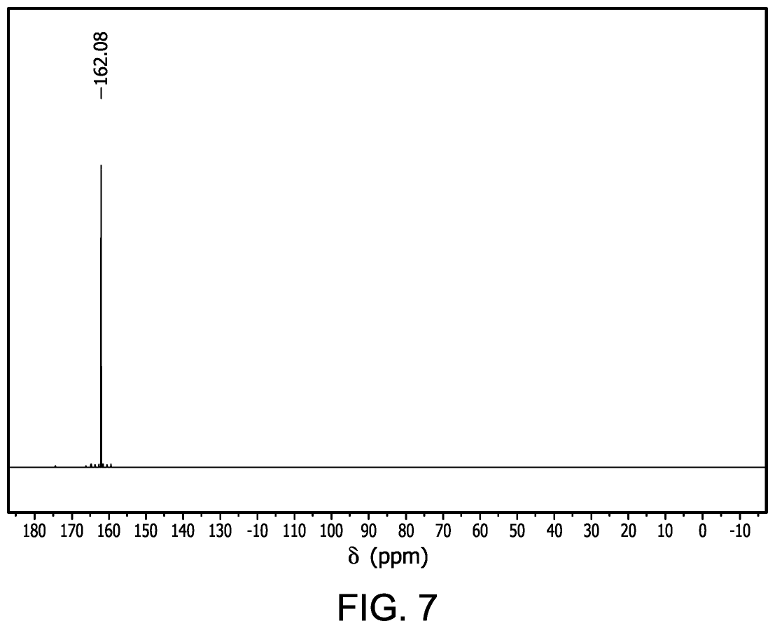

Characterization: ¹H NMR (500 MHz, C₆D₆) δ=3.13 (d, ³J_{HP}=11.7 Hz, 9H) ppm, FIG. 5; ¹³C NMR (125 Hz, C₆D₆) δ=208.7 (d, ²J_{CP}=40.2 Hz, trans-CO), 205.1 (d, ²J_{CP}=14.2 Hz, cis-CO), 51.2 (d, ²J_{CP}=3.1 Hz, CH₃) ppm, FIG. 6; ³¹P NMR (202 MHz, C₆D₆) δ=162.1 ppm, FIG. 7; B.P.: 57° C. (1.0×10⁻² mbar); TGA: See FIG. 1. M.p.: 17° C. (i.e., a lower melting point than Mo(CO)₆ or a liquid complex at RT).

### Example 2

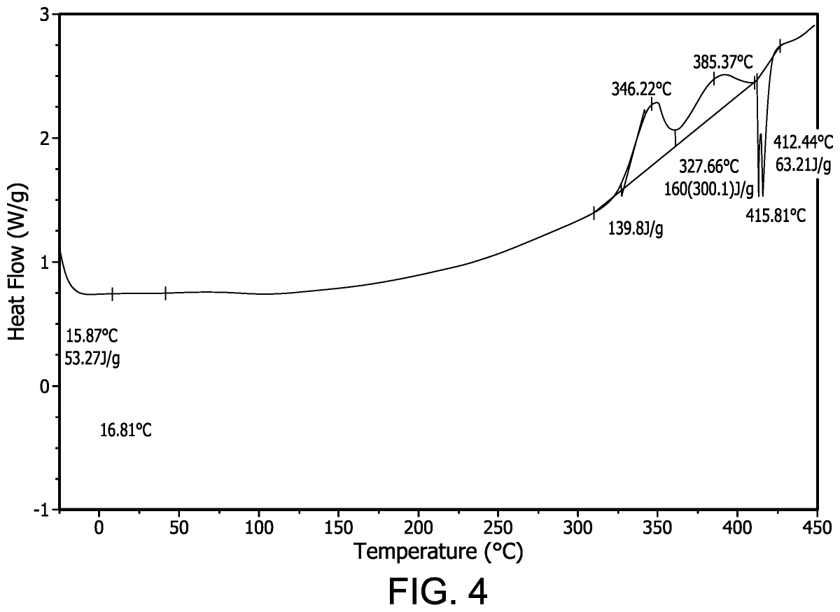

Differential scanning calorimetry (DSC) measurements were performed to demonstrate the higher thermal stability of the Mo(CO)₅P(OMe)₃ from Example 1 compared to Mo(CO)₆. As shown in FIG. 4, the DSC measurement demonstrates that the decomposition starts at 300° C. for the Mo(CO)₅P(OMe)₃. In comparison, Mo(CO)₆ decomposes at 150° C. Thus, the compounds with phosphorus-based ligands have a higher thermal stability than Mo(CO)₆.

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1. A compound comprising one or more of Formula I-A, Formula I-B and Formula I-C: 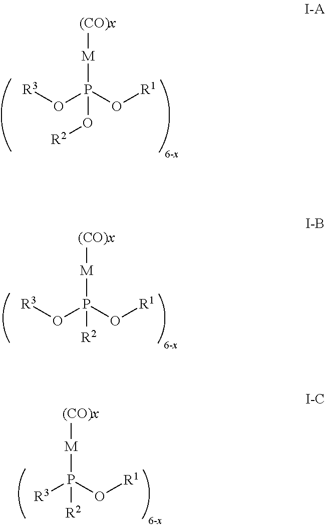
wherein
(i) M is one of Mo, W and Cr,
(ii) R² and R³ are each independently one of an unsubstituted linear C₁-C₈ alkyl group, an unsubstituted branched C₃-C₈ alkyl group, a linear or branched C₂-C₆ alkylene, a C₃-C₈ saturated cyclic alky and a C₅-C₈ arene, and
(iii) x=1, 2, 3, 4 or 5.

2-15. (canceled)

16. The compound of claim 1, wherein M is Mo.

17. The compound of claim 1, wherein M is W.

18. The compound of claim 1, wherein M is Cr.

19. The compound of claim 1, wherein one or more of R¹, R² and R³ is each independently an unsubstituted linear C₁-C₈ alkyl group.

20-27. (canceled)

28. The compound of claim 1, wherein one or more of R¹, R² and R³ is each independently an unsubstituted branched C₃-C₈ alkyl group.

29-33. (canceled)

34. The compound of claim 1, wherein one or more of R¹, R² and R³ is each independently a linear or branched C₂-C₆ alkylene.

35-37. (canceled)

38. The compound of claim 1, wherein one or more of R¹, R² and R³ is each independently a C₃-C₈ saturated cyclic alkyl.

39-44. (canceled)

45. The compound of claim 1, wherein one or more of R¹, R² and R³ is each independently a C₅-C₈arene.

46-92. (canceled)

93. The compound of claim 1, comprising one or more of

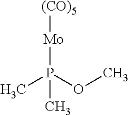

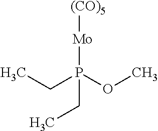

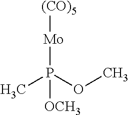

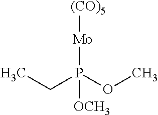

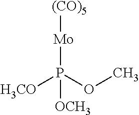

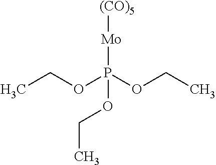

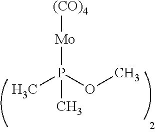

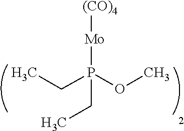

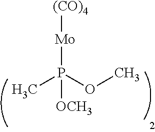

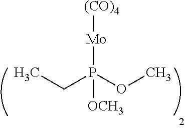

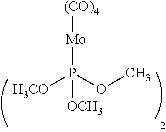

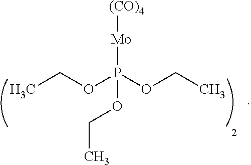

94. The compound of claim 1, comprising one or more of:

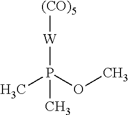

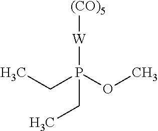

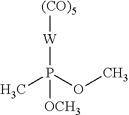

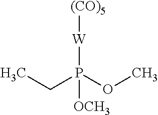

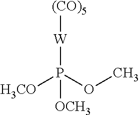

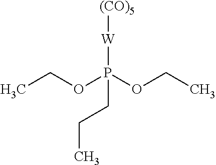

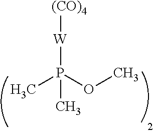

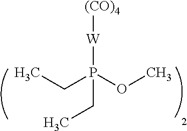

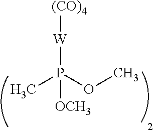

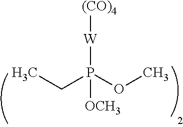

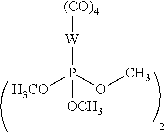

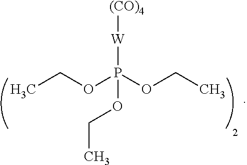

95. The compound of claim 1, comprising one or more of

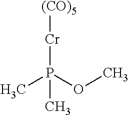

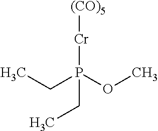

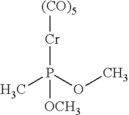

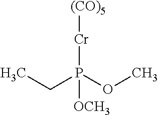

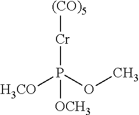

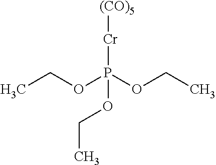

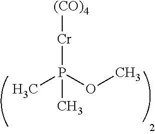

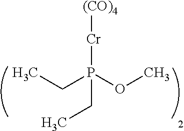

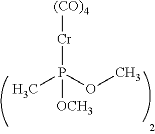

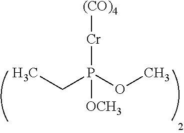

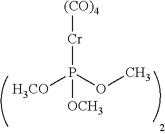

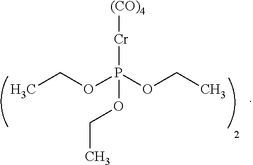

96. A composition comprising one or more compounds of claim 1.

97. A method for forming a transition metal-containing film on at least one surface of a substrate comprising:
a. providing the at least one surface of the substrate in a reaction vessel;
b. forming a transition metal-containing film on the at least one surface by a deposition process chosen from a chemical vapor deposition (CVD) process and an atomic layer deposition (ALD) process using the compound of claim 1 as a metal source compound for the deposition process.

98-101. (canceled)

102. A method of forming a transition metal-containing film via an atomic layer deposition (ALD) process or ALD-like process, the method comprising the steps of:
a. providing a substrate in a reaction vessel;
b. introducing into the reaction vessel the compound of claim 1;
c. purging the reaction vessel with a first purge gas;
d. introducing into the reaction vessel a source gas;
e. purging the reaction vessel with a second purge gas;
f. sequentially repeating steps b through e until a desired thickness of the transition metal-containing film is obtained.

103-108. (canceled)
